(19) United States
(12) Patent Application Publication
(10) Pub. No.: US 2009/0306914 A1
(43) Pub. Date: Dec. 10, 2009

(54) SYSTEM AND METHOD FOR MEASURING INPUT POWER OF POWER SUPPLIES

(75) Inventor: Isaac Cohen, Dix Hills, NY (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/274,917

(22) Filed: Nov. 20, 2008

Related U.S. Application Data
(60) Provisional application No. 61/058,758, filed on Jun. 4, 2008.

(51) Int. Cl. G01R 21/06

(52) U.S. Cl. 702/60

(57) ABSTRACT

A system and method is provided to determine input power of a power supply using an input section by dividing input section output power by an efficiency value of the input section. Measurements of operating parameters are obtained through sensing devices that may be previously provided to avoid increased expense and complexity associated with the addition of a current sensing device. The input section maybe a rectifier or PFC stage. Input section output power can be determined by measuring current in a downstream DC/DC converter or converters. The current drawn by the DC/DC converter(s) is used as the output current of the input section to determine output power of the input section. The efficiency value is obtained for an operating point of the input section based on operating parameter values, as indicated in a lookup table or algorithm providing the efficiency values. The calculated input power may also be used to determine input RMS current for the power supply.

### CROSS REFERENCE TO RELATED APPLICATIONS

This application claims the benefit of U.S. Provisional Application No. 61/058,758, filed Jun. 4, 2008, the entire contents of which are hereby incorporated herein by reference.

### STATEMENT REGARDING FEDERALLY SPONSORED RESEARCH OR DEVELOPMENT

N/A

### BACKGROUND

The present disclosure relates generally to measurement of power supply parameters, and more specifically to determining values of power supply input parameters.

In some power supply applications, the amount of energy consumed by a power supply is of interest for managing power delivery in a power supply system. For example, power management for a group of power supplies can be important for regulating energy consumption, which can translate into operating costs for an application utilizing one or more power supplies. In addition, it may be desirable to obtain a high power density with a low energy consumption to optimize power delivery resources, which are often used in conjunction with cooling systems to remove dissipated heat. By monitoring input parameters, such as power or current drawn by a power delivery system, a power management system can implement a protocol to attempt to optimize operating parameters for the given application. For example, a power supply administrator can manage power resources to control concentration of thermal loading, such as by shifting work loads to power distribution resources with available capacity. The determination of available capacity and loading is made possible through measurement of power supply input parameters.

A number of challenges arise in obtaining power supply input parameter values in relation to system cost and accuracy over a wide range of operational loads. According to one known implementation, input AC voltage and current are sampled, and input power is determined from the sampled values. For example, an input current sensor may be used to measure input current over an entire operational range of power supply loading. The input current sensor can take a number of forms, including a current transformer, Hall Effect sensor or an inline resistor having a small resistivity value. Each of these techniques for sensing input current can be relatively costly to implement, and may not achieve a desired level of performance. For example, the use of a current transformer as a current sensor is highly cost sensitive because of the desired range and accuracy to be provided by the current transformer. A Hall Effect device is similarly cost sensitive for the desired accuracy and dynamic range of operation to be sensed. An inline resistor is limited in its capability of measuring input current, as the resistance is usually maintained at a small value to avoid excessive heat dissipation. The small resistance value tends to reduce the effective range of operation available, as the entire range of operation may be represented in terms of millivolts, which can be difficult to gauge to obtain a consistent and precise accuracy for input current measurement. One way to overcome the drawbacks of the use of a current sense resistor is to employ a high precision amplifier with a high amplification value. However, such a high precision amplifier can be prohibitively expensive for power supply applications.

In general, AC to DC power supply power converters employ power factor correction (PFC) to reduce the reactive power and harmonics generated by the power supply. The PFC implementation generally attempts to maintain a power factor for the circuit close to unity. The PFC is typically controlled by measuring input and output voltage.

### SUMMARY

In accordance with the present disclosure, there is provided a system and method for determining power supply input parameter values, such as power, voltage and/or current, by measuring relevant parameters associated with a power supply input circuit in conjunction with an efficiency of the circuit. The parameter measurements can be relatively simple and inexpensive, especially in the case where the input circuit is a power factor correction (PFC) converter. The accuracy of PFC operation is generally very high, and typically has a high efficiency, for example, about 95% or higher. Parameter values that are already measured or are readily available in the power supply are used in conjunction with a determination of efficiency of the PFC to estimate input parameter values. Due to the relatively high efficiency of the PFC circuit, the generated input parameter value estimates have a relatively high degree of accuracy and consistency.

According to an exemplary embodiment of the disclosed system and method, a relatively high accuracy for determining input parameter values is maintained over a relatively large dynamic range. In addition, because the disclosed system and method utilizes parameter value measurements that are already existent in the power supply, any additional expense to implement the input parameter sensing is relatively small. The system and method of the present disclosure can be implemented as a continuous (analog) or digital solution, which implementation may depend upon the application involved.

In accordance with an exemplary embodiment, the disclosed system and method implements an efficiency reference for the PFC circuitry. Some embodiments can provide the efficiency reference based on a lookup table or an algorithm, or both. The efficiency reference indicates efficiency values for the PFC circuitry at given operating points. For example, the efficiency values may be determined for a given operating point based on PFC input voltage, output current and/or temperature. These or other circuit parameters may be provided to the efficiency reference, which can then produce an efficiency value based on the operating point indicated by the circuit parameters.

According to another exemplary embodiment of the disclosed system and method, input parameter values in a power supply with a frontend noise filter, such as an EMI filter, can be determined based on knowledge of the values of the components used to construct the noise filter. The disclosed system and method can be used to determine an estimate for input RMS current, for example, which can then be used with calculations involving reactive components to determine the overall input RMS current and the current draw on the noise filter components.

In accordance with another exemplary embodiment of the disclosed system and method, values for the above-mentioned PFC efficiency reference in the form of a lookup table or algorithm can be determined empirically by taking measurements on a relatively small number of power supplies having a substantially similar configuration. The empirical measurements are used to determine values to be used in the lookup table or algorithm. The efficiency values and their associated operating points, as determined by the empirical measurements, can be stored in the lookup table or algorithm as a discrete number of data points that can be interpolated, or as coefficients or other algorithmic settings to permit a given efficiency value to be determined based on a given operating point for the power supply.

### BRIEF DESCRIPTION OF THE SEVERAL VIEWS OF THE DRAWINGS

The disclosed system and method is described in greater detail below, with reference to the accompanying drawings, in which:

FIG. 1 is a circuit block diagram of current sense mechanisms to determine input power;

FIG. 2 is a circuit block diagram of an exemplary embodiment of the disclosed system and method;

FIG. 3 is a circuit block diagram of an exemplary embodiment of the disclosed system and method;

FIG. 4 is a flow chart illustrating an exemplary embodiment of the disclosed system and method;

FIG. 5 is a flow chart illustrating an exemplary embodiment of the disclosed system and method; and

FIGS. 6a-6c are graphs illustrating a comparison of actual input power with estimated input power in accordance with exemplary embodiments of the disclosed system and method.

### DETAILED DESCRIPTION

The present application is based on and claims priority of U.S. Provisional Application No. 61/058,758, filed Jun. 4, 2008, the entire contents of which is hereby incorporated herein by reference.

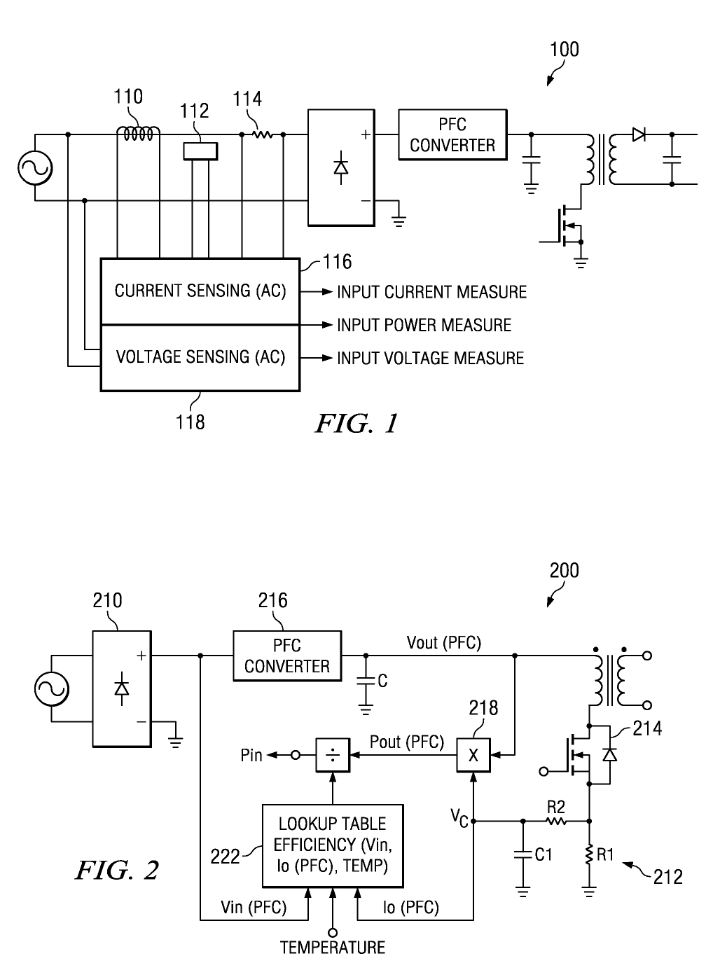

Referring to FIG. 1, an AC-DC converter 100 illustrates various types of current sensing devices for determining input current or power. A current transformer 110 measures AC input current by providing a step-down AC current proportional to input current. A Hall Effect sensor 112 measures input AC current by sensing magnetic fields produced by the AC input. A current sense resistor 114 senses input current as a function of voltage, which voltage is measured to determine current flow through current sense resistor 114. Each of devices 110, 112, 114 has compensation mechanisms built into the devices or into a current sensing control 116. Current sensing devices 110, 112 and 114 are relatively expensive to implement, especially with the compensation circuitry provide in the devices themselves or in current sensing control 116, as compared with the overall cost of power supply 100. The relatively high cost of input current sensing is especially pronounced when power supply 100 operates with “universal” input voltages, such as input voltages in the range of from about 85 to about 265 VAC, for example. In such a configuration, the components that make up the current sensing devices are rated for higher levels of current, leading to greater costs, as well as greater complexity because of the wider range of measurement. For example, it is desirable to have a small resistor value for resistive current sensing device 114 to avoid excessive power dissipation. However, the small resistor value leads to lower sensitivity and signal to noise ratio, which in turn leads to the addition of complex circuitry to produce a current signal of acceptable accuracy.

In contrast to current sensing devices 110, 112 and 114, a voltage sensing device is relatively inexpensive and less complex, even for significant voltage ranges. A voltage sensing control 118 can incorporate a number of different types of voltage sensing devices including resistors, certain types of switches or other active or passive components. By multiplying the current value from current sensing control 116 and the voltage value from voltage sensing control 118 and averaging the result, a measure of input power absorbed by power supply 100 can be derived.

Referring now to FIG. 2, a circuit block diagram of a power supply 200 illustrates an exemplary embodiment of the disclosed system and method. Power supply 200 includes a current measuring network 212 that operates to measure current through a primary switch 214. The average current that flows through switch 214 is approximately the same as that output by a PFC converter 216. The current in switch 214 is sensed by resistor R1 and applied to an averaging circuit composed of a capacitor C1 and a resistor R2. A voltage Vc across capacitor C1 is proportional to the average output current of converter 216, and provides a current measure used to calculate output power of PFC converter 216. A multiplier 218 multiplies an output voltage Vout of PFC converter 216 and voltage Vc on capacitor C1. The output of multiplier 218 provides a value that is proportional to the output power Pout of PFC converter 216.

Voltage Vc is also applied to a block 222, which is a lookup table that stores a matrix containing the values of typical efficiencies of PFC converter 216 as a function of input voltage, output power or current and optionally the operating temperature of the system. Block 222 thus provides an efficiency value reference source that receives circuit parameter values in relation to an operating point of power supply 200, and produces an efficiency value based on the value(s) of the input operating parameter(s). Block 222 may be implemented in a memory store, such as that associated with a microcontroller or other control, processing or storage components used to implement a control for power supply 200. Block 222 is represented in the exemplary embodiment in FIG. 4 as a lookup table that provides an efficiency value of PFC converter 216, based on operational parameters. For example, various operating parameters of PFC converter 216, such as input voltage, output current and temperature, are applied to block 222 to determine the efficiency of PFC converter 216 at the operating point indicated by the parameters. PFC converter 216 may have variable efficiency over its operating range. According to an exemplary embodiment, the amount of data stored in the lookup table represented as block 222 is minimized, to conserve storage, for example. The efficiency values stored in the lookup table are interpolated for values of input voltage Vin, output current and/or temperature that fall within the respective stored values of each of these parameters.

Block 222 thus provides an efficiency output value for PFC converter 216 based on empirical data describing the characteristic operation of PFC converter 216, as influenced by operating parameters such as input voltage, output current and/or temperature, for example. The efficiency value for PFC converter 216 at the given operating point determined by the operating parameters applied to block 222 is used with the calculated output power value of PFC converter 216 to determine a value of input power Pin for PFC converter 216. The calculated input power Pin is given as the output power Pout divided by the efficiency of PFC converter 216. The value for input power Pin derived for PFC converter 216 closely approximates input power to a rectifier 210, which represents input power for power supply 200. Accordingly, the calculated value for input power Pin can be used to determine energy consumption for power supply 200, for example within the context of managing power capacity in a power delivery and management system.

In addition to the presence of PFC converter 216, typical power supplies sense current in the switches of the DC/DC converter, as illustrated by network 212 used to sense current through primary switch 214. Because the current flowing through switch 214, and thus output from PFC converter 216, is readily available, no significant additional components need be provided to sense current or to implement the system of power supply 200 illustrated in FIG. 2. Furthermore, the input and output voltage of PFC converter 216 is generally available in commercial power supply designs, since those parameters are used in the operation of PFC converter to maintain a high power factor and efficiency level. Therefore, the implementation of power supply 200 illustrated in FIG. 2 can be readily obtained with existing components and sensed values, without the addition of expensive and complex current sensing devices. The absence of expensive and complex current sensing devices connected to an input of rectifier 210 greatly reduces the cost and difficulty of manufacturing power supply 200, while the functionality of determining input power is implemented.

The current through switch 214 measured by network 212 can be the average or integrated value of the input current of the DC/DC converter. A number of DC/DC converters can be employed in parallel that take advantage of the disclosed system and method as well.

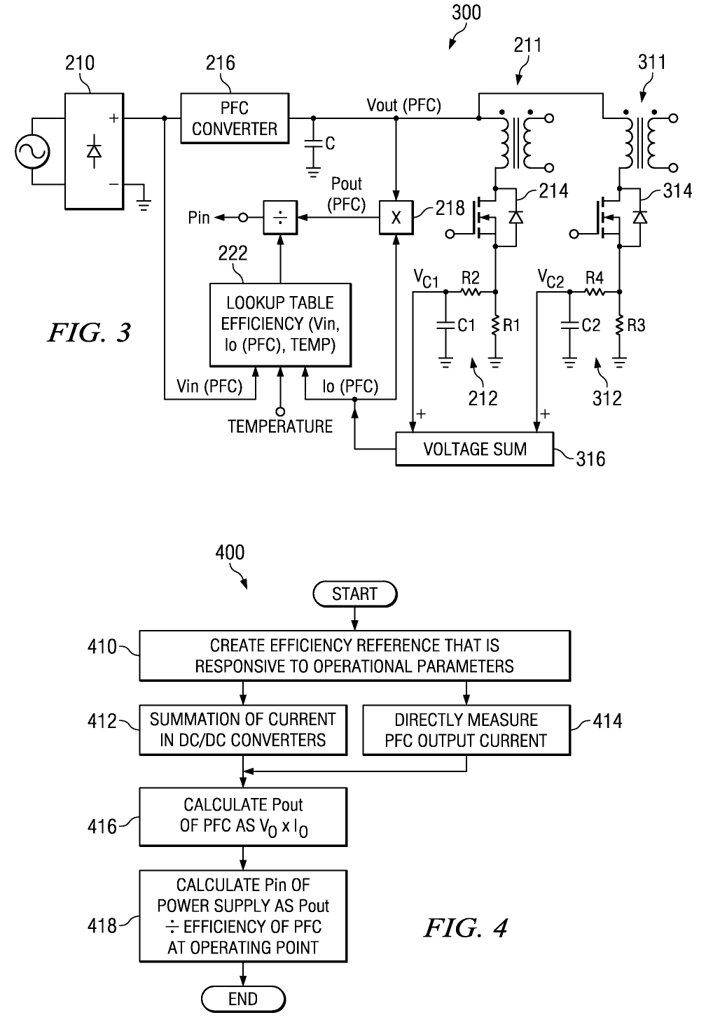

Referring now to FIG. 3, a power supply 300 with DC/DC converter stages 211, 311 is illustrated. The input of DC/DC converter stages 211, 311 is connected to an output of PFC converter 216. Stages 211, 311 have an input voltage that is taken from the output of PFC converter 216. Each stage 211, 311 may draw different amounts of current, as determined by the current flowing through respective switches 214, 314. Current sensing networks 212, 312 obtain an average value for current flowing through respective switches 214, 314 in the form of representative voltages Vc1 and Vc2. Voltages Vc1 and Vc2 are added together by summing device 316. Device 316 provides a voltage output that represents a sum of voltages Vc1 and Vc2, which in turn represents an average output current of PFC converter 216. The output of summing device 316 is applied to multiplier 218 to calculate the output power Pout of PFC converter 216 and to extract and the efficiency value derived from block 222. The efficiency value and output power Pout of PFC converter 216 are combined to produce a value for input power Pin, which represents the input power of power supply 300. As with power supply 200, no additional current sense devices need be provided in power supply 300 to obtain a fairly accurate estimate of input power Pin.

Referring now to FIG. 4, an exemplary embodiment of a method according to the present disclosure is illustrated. The method begins with the formation of an efficiency reference that is created to be responsive to operational parameters of the power supply, as illustrated in block 410. The operational parameters may be, for example, PFC input voltage, PFC output current, temperature, or any other system parameter that can contribute to providing a determination of the efficiency of the PFC at a given operating point. The efficiency reference can be a table lookup, in which efficiency values associated with discrete operating points in the range of operation for the PFC are stored and retrieved in response to a given operating point determined by the operational parameters. The table lookup values may be interpolated between different points of efficiency given an applied operating point that falls between two discrete operating points stored in the lookup table.

In addition, or alternately, the efficiency reference can be an algorithm that provides an efficiency value output based on a given applied operational point that depends upon the input operational parameters. The algorithm can reflect a given characteristic curve representative of the PFC, which may reflect the PFC configuration or construction. The table lookup discussed above may also be related to or derived from the characteristic curve or the algorithm used to implement the efficiency reference.

According to one exemplary embodiment, the efficiency reference can be constructed during manufacture of the power supply or PFC, in which operational parameters are applied to the power supply or PFC, and empirical efficiency values are determined for the given operating points and stored in a memory location. The efficiency reference can be formed by taking a sample number of power supplies or PFCs to be evaluated, operating the power supply or PFC at given operating points, and measuring and storing the efficiency values for the given operating points. The stored efficiency values for the given operating points can then be replicated and stored for the sample or other power supplies or PFCs, such that the empirically obtained data need not be taken for each individual power supply or PFC. In the exemplary embodiment where the efficiency reference is implemented as an algorithm, various algorithmic parameters can be adjusted based on empirical measurements of a sample number of power supplies or PFCs, as described above, and stored for use with other power supplies or PFCs.

In flowchart 400, the exemplary embodiment of the method according to the present disclosure operates by summing the current in the DC/DC converters that are connected to the PFC output, as illustrated in block 412. The current in the DC/DC converters is obtained through already existent current measuring mechanisms, which are generally present to measure current in switches in the DC/DC converters. As an alternative, block 414 illustrates the optional method of determining PFC output current directly, such as with a shunt or other current measuring components. When a current sensing device is implemented on the output of the PFC, the current sensing device need not have as high a rating as a current sensing device that is implemented on the AC line input, meaning that some savings in implementing a current sensing device can be achieved in this alternative embodiment. Once a representative value is obtained to indicate PFC output current, the output power of the PFC can be calculated as the product of output voltage and output current of the PFC, as illustrated in block 416. Once the output power of the PFC is calculated, the efficiency reference can be used to provide an efficiency value at the given operating point for the PFC, and input power can be calculated by dividing the output power by the efficiency of the PFC at the operating point, as illustrated in block 418.

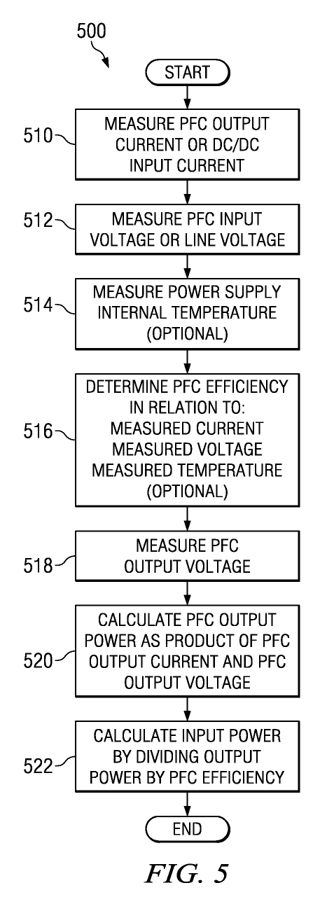

Referring now to FIG. 5, another flowchart 500 illustrates a process for determining input power in accordance with an exemplary embodiment of the disclosed method. In block 510, the output current of the PFC is measured, such as with a direct measurement, or by measuring the input current in the DC/DC converter(s). The method obtains a measure of the PFC input voltage, or the line voltage of the power supply in step 512. Optionally, a temperature of the power supply is measured to obtain an operating point parameter value, as illustrated in block 514. Block 516 illustrates the determination of PFC efficiency in relation to a given operating point that may involve a measured current, voltage and/or temperature. In block 518, the PFC output voltage is measured according to any convenient technique as is well understood by those of ordinary skill in the relevant art. In general, the output voltage of the PFC is measured and available from standard PFC controllers that control the PFC stage based on PFC input and output voltage. In block 520, PFC output power is calculated as a product of PFC output current and PFC output voltage, where the PFC output current may be represented as input current of the DC/DC converter(s). In block 522, the power supply input power is calculated by dividing the output power value of the PFC obtained in block 520 by the PFC efficiency obtained in block 516. The calculated input power can then be used for any particular application or purpose, including power resource management or distribution. As discussed previously, the calculated or estimated value of input power Pin can be produced by a microcontroller or other processing component configured to conduct arithmetic operations and store information related to the efficiency of the PFC stage at various operating points. The value of input power Pin can be supplied in analog or digital form, to be used in a host or system control to establish a power management system.

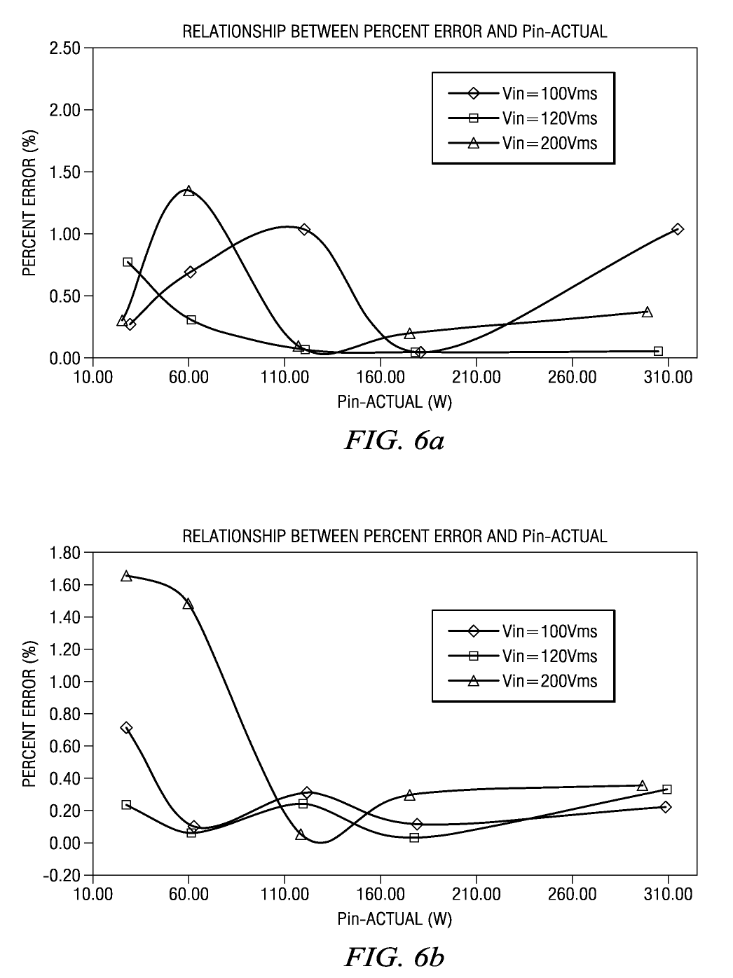

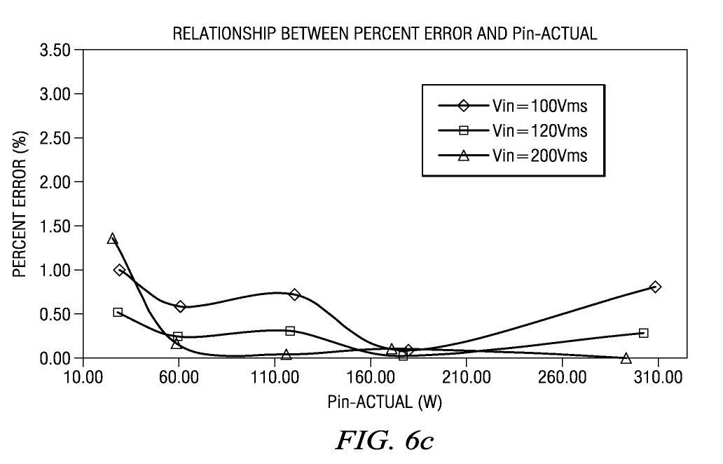

Referring now to FIGS. 6a-6c, empirical results of percent error in relation to actual input power Pin is illustrated. The graphical comparison of actual input power Pin versus percent error provides an indication of how the estimated input power Pin derived in accordance with the disclosed system and method compares with actual input power Pin. As FIGS. 6a-6c illustrate, actual input power Pin compares favorably with estimated input power Pin with the percent error being less than 1% for an input voltage Vin of 100 Vrms over a range of input power from 10 W to 310 W. With an input voltage Vin of 120 Vrms, the percent error is generally less than 0.5% over the range from 10 W to 310 W. With an input voltage Vin of 200 Vrms, the percent error is generally less than about 1.5% over the range of 10 W to 310 W. This fairly close agreement between actual input power Pin and estimated input power Pin validates the presently disclosed system and method for use in determining input power for a power supply with a PFC converter and DC/DC power converter(s), without requiring additional costly current or power sensing devices.

In addition to estimating input power of a power supply as discussed above, the presently disclosed system and method may also be used to determine input power when a front end noise filter, such as an EMI filter, is provided on the AC line input. Generally, a noise filter such as may be implemented on an AC line input is composed of passive components that have reactive characteristics, such as in the case of capacitors and inductors. By knowing the values and configuration of the passive components, an estimate for input rms current can be determined, based on the estimated input power Pin as determined in accordance with the disclosed system and method. For example, knowing the input power Pin, the input rms current drawn by the power supply can be determined by knowing the configuration and values of components in the front end noise filter. These types of calculations are well known to those of ordinary skill in the art and a further detailed discussion of the same is omitted.

In the above exemplary embodiments, the PFC converter has been described and illustrated as being a separate device from the DC/DC converter(s). However, any power supply with a PFC converter can be used in accordance with the presently disclosed system and method. For example, power supplies with an integrated PFC converter may employ the presently disclosed system and method.

Furthermore, while some embodiments include a current sensing device used in conjunction with a DC/DC converter, it is also possible to use a current sensing device on an output of a PFC converter to obtain an output current value to be used in determining output power and input power in accordance with the disclosed system and method. When a number of DC/DC converters are used with a given PFC converter, for example, by being attached to an output of a PFC converter, the input current of the DC/DC converters can be summed to obtain a value for output current of the PFC stage. Moreover, the efficiency reference for the PFC stage can be implemented in a number of different ways, including by a lookup table or an algorithm that approximates a characteristic efficiency curve for a PFC converter.

Also, input current can be calculated by dividing the input power by the rms value of the input voltage of the PFC converter. This input current value can be determined with a calculation that compensates for a line input noise filter. According to an exemplary embodiment, the calculated input current can be compensated for errors with appropriate compensation factors that can be in the form of a lookup table or algorithm, for example. In accordance with an exemplary embodiment, calculated input current is determined and compared to actual input current for a sampled set of power supplies to empirically determine correction factors for the calculated input current to approximate the actual input current. For example, in the case of the line input noise filter, reactive current drawn by an input EMI filter and the components of the filter can cause a displacement angle between the input current and the input voltage of the converter. The impact of the reactive current drawn by the input EMI filter and components can be significant at light load conditions. Because the nominal values of filter components are known, the nominal value of the reactive current can be calculated and used to adjust the input current correction factors, such as by adjusting the entries in a lookup table, for example. That is, with calculated input current for a PFC converter, input current for the power supply can be determined by calculating power supply input current based on the nominal component values in an input EMI filter, for example, with input current correction factors applied for the input EMI filter to arrive at a calculated value for a power supply input current. Therefore by maintaining input current correction factors, such as in a look-up table, for example, a calculated value for power supply input current can be obtained with a fair degree of accuracy in accordance with the disclosed system and method.

The disclosed system and method is not limited to power supplies having a PFC stage. The PFC stage serves as an input section that is a relatively direct source of operating parameters to implement the disclosed system and method. However, other input sections of the power supply may by used in accordance with the disclosed system an method. For example, a rectifier stage, such as rectifier 210, may be used as an input section with an evaluated efficiency that can be stored for various operating conditions. Accordingly, input power can be determined by obtaining a value for rectifier output power, which is then divided by a retrieved efficiency value of the rectifier at the given operating point.

The disclosed system and method provide a relatively good accuracy of better than about 2% in determining input power. This relatively good accuracy is achieved without extensive production line calibration, or the addition of costly current or power sensing devices. The power measurement accuracy provided in accordance with the disclosed system and method is not affected by input voltage/current displacement and/or harmonic distortions. Furthermore, the implementation of the disclosed system and method can be achieved in either continuous (analog) or digital controllers or systems. For example, in an analog system a microcontroller is typically employed that provides watchdog and communication functions. Such a microcontroller can be programmed to support power measurement in accordance with the disclosed system and method. In a digital system, the digital control circuits can easily be modified to include a power measurement algorithm in accordance with the disclosed system and method. For example, the block diagrams illustrated in FIGS. 2 and 3 can be easily implemented in a digital control circuit.

It should be emphasized that the above-described embodiments of the present invention are merely possible examples of implementations, merely set forth for a clear understanding of the principles of the invention. Many variations and modifications may be made to the above-described embodiments of the invention without departing substantially from the spirit and principles of the invention. All such modifications and variations are intended to be included herein within the scope of this disclosure and the present invention and protected by the following claims.

What is claimed is:

1. A system for determining input power for a power supply, the system comprising:
an efficiency reference source coupled to an input section of the power supply to permit the efficiency reference source to receive operating parameters related to operation of the input section;
at least one efficiency reference value stored in the efficiency reference source and being associated with at least one operating point of the input section; and
a processing component coupled to the efficiency reference source and being operable to combine the at least one efficiency reference value and an indication of output power of the input section to provide an input power value for the power supply.

2. The system according to claim 1, further comprising a current sensing device coupled to an output of the input section and to the efficiency reference source to provide output current information from the input section to the efficiency reference source.

3. The system according to claim 1, further comprising an output power calculation mechanism coupled to an output of the input section and being operable to produce the indication of output power of the input section.

4. The system according to claim 3, further comprising an input power calculation mechanism coupled to the efficiency reference source and operable to combine the indication of output power and the at least one efficiency reference value to provide the input power value.

5. The system according to claim 4, further comprising the input power calculation mechanism being operable to combine the indication of output power and the efficiency reference value in accordance with the following equation: Pin=Pout/efficiency reference value.

6. The system according to claim 1, wherein the input section further comprises a PFC section.

7. The system according to claim 6, wherein the operating parameters further comprise one or more of PFC section input voltage, output current or temperature.

8. The system according to claim 2, wherein the current sensing device measures current in a DC/DC converter stage.

9. The system according to claim 8, wherein: the DC/DC converter stage comprises a plurality of DC/DC converters; and
the current sensing device comprises at least one current sense device for each DC/DC converter of the plurality.

10. The system according to claim 9, further comprising a summing mechanism coupled to the at least one current sensing device for each of the DC/DC converters in the plurality to receive a current sense value from each of the at least one current sense device for each of the DC/DC converters and produce a representation of a sum of the currents in the DC/DC converter stage, the summing mechanism being coupled to the efficiency reference source.

11. The system according to claim 1, wherein the efficiency reference source comprises one or more of a lookup table or algorithm.

12. The system according to claim 11, wherein the efficiency reference source further comprises memory storage to maintain the at least one efficiency reference value associated with the at least one operating point.

13. A method for determining input power in a power supply, the method comprising:
obtaining an indication of output power of an input section of the power supply;
obtaining an efficiency reference value related to an operating point of the input section; and
dividing the indication of output power by the efficiency reference value to obtain an indication of input power for the input section.

14. The method according to claim 13 further comprising sensing output current of the input section to contribute to determining the indication of output power.

15. The method according to claim 14, further comprising obtaining an indication of output voltage of the input section and multiplying the indication of output voltage by the indication of output current to obtain an indication of output power for the input section.

16. The method according to claim 13, further comprising using operating parameters of the input section to determine an efficiency reference value for the input section.

17. The method according to claim 13, further comprising using a PFC section as the input section.

18. The method according to claim 13, further comprising obtaining an indication of current flowing through each of a plurality of DC/DC converters coupled to an output of the PFC section.

19. The method according to claim 18, further comprising averaging the indication of current in each of the plurality of DC/DC converters.

20. The method according to claim 18, further comprising integrating the indication of current in each of the DC/DC converters in the plurality.

21. The method according to claim 13, obtaining the efficiency reference value from one or more of a lookup table or algorithm.
